(19) United States
(12) Patent Application Publication
(10) Pub. No.: US 2026/0250014 A1
(43) Pub. Date: Aug. 27, 2026

(54) DEVELOPMENT AND MANAGEMENT OF PARAMETRIC DATA ITEMS FOR BUILT-IN TESTING OF AIRCRAFT ELECTRICAL POWER GENERATION SYSTEMS OR OTHER COMPONENTS

(71) Applicant: Hamilton Sundstrand Corporation, Charlotte, NC (US)

(72) Inventors: Kamaraj Thangavelu, Rockford, IL (US); Billy J. Mordecai, Rockford, IL (US); Paul J. Peterson, Rockford, IL (US); Abhay V. Munshi, Lake in the Hills, IL (US)

(21) Appl. No.: 19/445,208

(22) Filed: Jan. 9, 2026

Related U.S. Application Data
(60) Provisional application No. 63/762,480, filed on Feb. 24, 2025.

(51) Int. Cl. B64D 45/00

(52) U.S. Cl. CPC B64D 45/00; B64D 2045/0085; B64D 2221/00

(57) ABSTRACT

A method includes obtaining an ordering of built-in test equipment (BITE) functions to be executed for an aircraft. The method also includes, for each BITE function of the ordering, retrieving and executing at least one parametric data item (PDI) implementing the BITE function. At least some of the PDIs implementing the BITE functions are independent of one another such that a modification to one PDI does not alter others of the other PDIs. At least some of the PDIs are reusable across different aircraft having different equipment configurations.

### CROSS-REFERENCE TO RELATED APPLICATION AND PRIORITY CLAIM

This application claims priority under 35 U.S.C. § 119(e) to U.S. Provisional Patent Application No. 63/762,480 filed on Feb. 24, 2025, which is hereby incorporated by reference in its entirety.

### TECHNICAL FIELD

This disclosure relates generally to self-testing of aircraft electrical power generation systems or other components. More specifically, this disclosure relates to the development and management of parametric data items for built-in testing of aircraft electrical power generation systems or other components.

### BACKGROUND

Built-in test equipment (BITE) functions are often used with aircraft electrical power generation systems and other components to continuously monitor the health and performance of the power generation systems and other components, such as by monitoring the health and performance of generators, buses, transformers, and circuit breakers within the systems. BITE functions typically support automated testing capabilities, meaning the BITE functions can be used to provide continuous monitoring and diagnostics of the power generation systems and other components of the aircraft. This can help to ensure that critical parameters like voltages, currents, frequencies, and loads are within safe operating ranges. Faults or other issues detected by the BITE functions can be used to support maintenance or other functions involving the aircraft.

### SUMMARY

This disclosure relates to the development and management of parametric data items for built-in testing of aircraft electrical power generation systems or other components.

In some examples, a method may include obtaining an ordering of built-in test equipment (BITE) functions to be executed for an aircraft. The method may also include, for each BITE function of the ordering, retrieving and executing at least one parametric data item (PDI) implementing the BITE function. At least some of the PDIs implementing the BITE functions may be independent of one another such that a modification to one PDI does not alter others of the other PDIs. At least some of the PDIs may be reusable across different aircraft having different equipment configurations.

In other examples, an apparatus may include at least one memory configured to store PDIs implementing BITE functions. The apparatus may also include at least one processing device configured to obtain an ordering of the BITE functions to be executed for an aircraft and, for each BITE function of the ordering, retrieve and execute at least one PDI implementing the BITE function. At least some of the PDIs implementing the BITE functions may be independent of one another such that a modification to one PDI does not alter others of the other PDIs. At least some of the PDIs may be reusable across different aircraft having different equipment configurations.

In still other examples, a non-transitory machine-readable medium may contain instructions that when executed cause at least one processor to obtain an ordering of BITE functions to be executed for an aircraft. The non-transitory machine-readable medium may also contain instructions that when executed cause the at least one processor, for each BITE function of the ordering, to retrieve and execute at least one PDI implementing the BITE function. At least some of the PDIs implementing the BITE functions may be independent of one another such that a modification to one PDI does not alter others of the other PDIs. At least some of the PDIs may be reusable across different aircraft having different equipment configurations.

Any single one or any combination of the following features may be used with the above examples.

The ordering of the BITE functions may be obtained from an ordering table using a BITE engine.

For each BITE function of the ordering, the at least one PDI implementing the BITE function may be retrieved and executed by accessing an index table using a PDI index engine and retrieving the at least one PDI implementing the BITE function using a PDI processing engine. The index table may be accessed based on an identifier provided by the BITE engine. The at least one PDI may be retrieved using at least one memory address provided by the PDI index engine from the index table.

The ordering table may identify multiple orderings of BITE functions.

Fault data associated with execution of at least one of the PDIs may be provided to the BITE engine.

At least one of the BITE functions may be configured to monitor an electrical power generation system of the aircraft, a control circuit for the electrical power generation system of the aircraft, or both.

The different equipment configurations may include different electrical power generation systems and/or different control circuits for electrical power generation systems.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example aircraft having at least one control system supporting parametric data items for built-in testing of aircraft electrical power generation systems or other components in accordance with this disclosure;

FIG. 2 illustrates an example control system for an aircraft supporting parametric data items for built-in testing of aircraft electrical power generation systems or other components in accordance with this disclosure;

FIGS. 3A through 3C illustrate example portions of the control system of FIG. 2 with data address mapping and reconfigured data address mapping in accordance with this disclosure;

FIG. 4 illustrates an example architecture supporting the development and management of parametric data items for built-in testing of aircraft electrical power generation systems or other components in accordance with this disclosure;

FIG. 5 illustrates an example device for the development and management of parametric data items for built-in testing of aircraft electrical power generation systems or other components in accordance with this disclosure; and

FIG. 6 illustrates an example method for the development and management of parametric data items for built-in testing of aircraft electrical power generation systems or other components in accordance with this disclosure.

### DETAILED DESCRIPTION

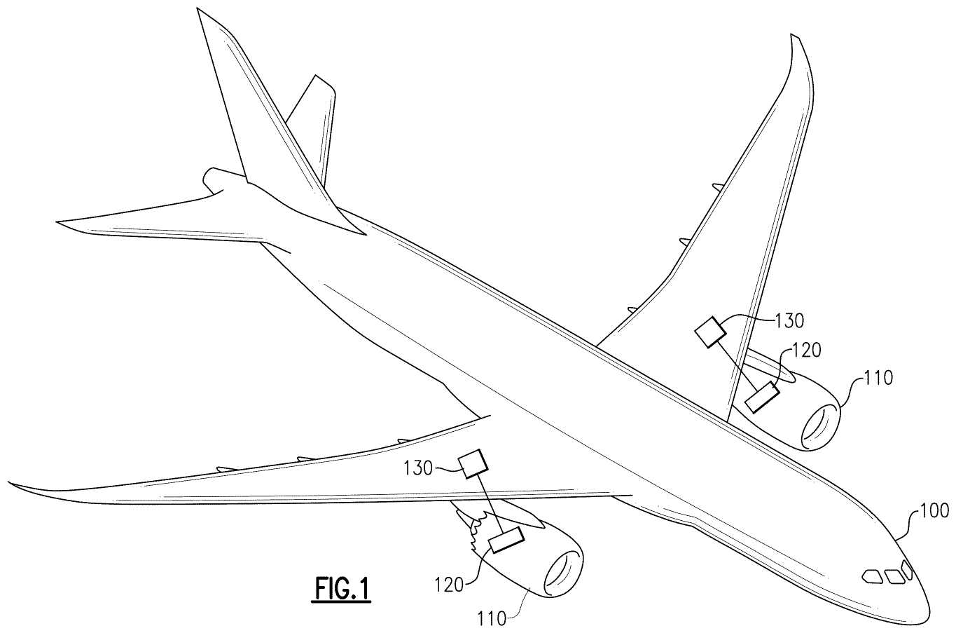

FIGS. 1 through 6, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, built-in test equipment (BITE) functions are often used with aircraft electrical power generation systems and other components to continuously monitor the health and performance of the power generation systems and other components, such as by monitoring the health and performance of generators, buses, transformers, and circuit breakers within the systems. BITE functions typically support automated testing capabilities, meaning the BITE functions can be used to provide continuous monitoring and diagnostics of the power generation systems and other components of the aircraft. This can help to ensure that critical parameters like voltages, currents, frequencies, and loads are within safe operating ranges. Faults or other issues detected by the BITE functions can be used to support maintenance or other functions involving the aircraft. In this way, the BITE functions can play a critical role in maintaining the reliability and safety of aircraft electrical systems.

Unfortunately, BITE functions for aircraft are often complex and can be highly variable across different aircraft. Traditionally, BITE functions are designed for specific control circuits and specific power generation systems and are integrated with other critical functions, which generally results in a lack of flexibility and adaptability across different electrical power generation systems and control circuits. Instead, current approaches design, develop, verify, and certify the BITE functions for each individual configuration. Among other things, this specificity can lead to inefficiencies and increased costs due to the need for tailored solutions for each power generation system and control circuit configuration.

This disclosure provides various techniques supporting the development and management of parametric data items for built-in testing of aircraft electrical power generation systems or other components. Among other things, these techniques provide a parametric approach to designing BITE functions that are adaptable to a wide range of electric power generation system and control circuit configurations. By using a parametric approach, these techniques allow for the generic application of BITE functions, irrespective of the specific electric power generation system and control circuit configuration being used in an aircraft. In other words, BITE functions can be generalized, providing parametric control to the BITE functions in order to operate under various power generation system and control circuit configurations. This can help to streamline the development and implementation of BITE functions, reduce the need for customized solutions, reduce maintenance costs and/or consumables costs, and enhance the reliability and efficiency of aircraft power generation systems.

The disclosed techniques allow for the development of each BITE function as one or more parametric data items (PDIs). Each PDI can be created or otherwise designed as a field-loadable item. Using this approach, the majority of BITE functions can remain unchanged for most electrical power generation system and control circuit configurations. For any BITE function that needs modification based on the configuration, the individual BITE function's PDI(s) can be modified without impacting all other BITE function PDIs. As a result, changes to one or some BITE function PDIs can have little or no impact to other critical functions and/or other BITE function PDIs. This enables the reusability of BITE functions across various electrical power generation system and control circuit configurations, improving reliability and reducing BITE development efforts and costs significantly. These techniques therefore introduce a parametric approach to designing BITE functions that are adaptable to a wide range of electric power generation system and control circuit architectures.

FIG. 1 illustrates an example aircraft 100 having at least one control system supporting parametric data items for built-in testing of aircraft electrical power generation systems or other components in accordance with this disclosure. As shown in FIG. 1, the aircraft 100 includes one or more gas turbine engines 110. Each of the gas turbine engines 110 drives a generator 120. A control system 130 communicates to control each generator 120. As described in more detail below, each control system 130 could implement BITE functions using PDIs. In this example, each control system 130 may form part of a generator control unit (GCU) or other larger control circuit. However, other control systems 130, which control various avionic hardware and systems throughout the aircraft 100, could implement BITE functions using PDIs as described in more detail below.

Although FIG. 1 illustrates one example of an aircraft 100 having at least one control system 130 supporting parametric data items for built-in testing of aircraft electrical power generation systems or other components, various changes may be made to FIG. 1. For example, the aircraft 100 may have any other suitable form factor. Also, various components in FIG. 1 may be combined, further subdivided, replicated, omitted, or rearranged and additional components may be added according to particular needs.

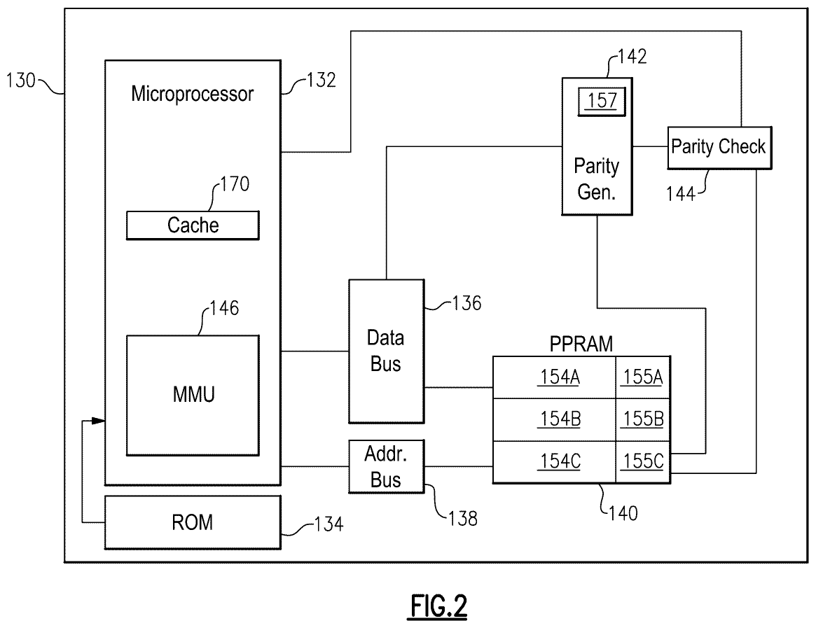

FIG. 2 illustrates an example control system 130 for an aircraft supporting parametric data items for built-in testing of aircraft electrical power generation systems or other components in accordance with this disclosure. For ease of explanation, the control system 130 shown in FIG. 2 is described as being used in the aircraft 100 shown in FIG. 1, such as to control a generator 120 of the aircraft 100. However, the control system 130 shown in FIG. 2 could be used with any other suitable type of aircraft and/or to control or monitor any other suitable type of aircraft equipment.

As shown in FIG. 2, the control system 130 includes a microprocessor 132, a read-only memory (ROM) 134, a data bus 136, an address bus 138, a parity-protected random access memory (PPRAM) 140, a parity generator 142, and a parity checker 144. The microprocessor 132 can include a memory management unit (MMU) 146 and a cache 170. The ROM 134 can be in communication with the microprocessor 132 so that the microprocessor 132 can move compressed or other static data from the ROM 134 into the PPRAM 140 as multiple copies 154A-154C of bytes of static data. Static data represents data that is not deleted or modified once created. For example, the bytes of data received from the ROM 134 can be unzipped or uncompressed and written into the PPRAM 140 by the microprocessor 132 for storage and use by the control system 130, thereby creating static data copies 154A-154C.

The microprocessor 132 can write the static data copies 154A-154C to the PPRAM 140 through the data bus 136 while retaining and assigning addresses of the static data copies 154A-154C stored in the PPRAM 140 through the address bus 138. The static data copies 154A-154C can be utilized when a first static data copy is determined to be corrupted. Due to memory size constraints and single-event upset (SEU) protection requirements, the static data copies 154A-154C can be stored on the PPRAM 140 for access, as opposed to on the ROM 134, so that corrupted static data copies 154A-154C can be overwritten and corrected.

The data bus 136 can be configured to allow the microprocessor 132 to write data to the PPRAM 140 and read data from PPRAM 140. For example, when the data bus 136 is writing the static data copies 154A-154C, the data can be sent to and stored in the PPRAM 140. When the microprocessor 132 reads data through the data bus 136, the stored data copies 154A-154C in the PPRAM 140 can be accessed for use by the control system 130. In some cases, the MMU 146 can map address locations for the static data copies 154A-154C at startup. Also, in some cases, the cache 170 can be disabled at startup for the static data copies 154A-154C. The address bus 138 can contain the requested address location of a program of the microprocessor 132 to access a given memory location in the PPRAM 140. The microprocessor 132 may be able to access the multiple static data copies 154A-154C stored in the PPRAM 140 by using the MMU 146 to point to the address of a particular static data copy 154A-154C and reading the static data copy 154A-154C using the data bus 136.

When the data bus 136 operates to either write data or read data for the microprocessor 132, the static data copy 154A-154C being written or read can also be sent to the parity generator 142. The parity generator 142 can take each static data copy 154A-154C and create a parity bit 155A-155C for each byte. Alternatively, parity may be determined on a different number of bits, such 4, 16, 32, 64, or other numbers of bits. The parity bit 155A-155C can be either a one or a zero (depending on whether odd parity checking or even parity checking is being employed) and can be stored in the PPRAM 140 with the corresponding static data copy 154A-154C.

In some embodiments, the control system 130 can employ odd parity checking as shown by example in Table 1 below. In this example, the parity generator 142 can count the number of ones in each byte of data and determine the parity bit 155A-155C to be created and added to each byte such that the nine bits (or other number of bits) have an odd number of ones. If there is an even number of bits with the value 1, the parity bit 155A-155C can be assigned the value 1. If there are an odd number of bits with the value 1, the parity bit 155A-155C can be assigned the value 0.

TABLE 1

| Sample Data | Number of Ones | Parity | Number of Ones |
|---|---|---|---|
| Bits in a Byte | in Data Byte | Bit | Including Parity Bit |
| 00000000 | 0 | 1 | 1 |
| 10110011 | 5 | 0 | 5 |
| 10010100 | 3 | 0 | 3 |
| 11111111 | 8 | 1 | 9 |

In other embodiments, the control system 130 can employ even parity checking as shown by example in Table 2. In this example, the parity generator 142 can generate a parity bit 155A-155C such that the nine bits (or other number of bits) have an even number of ones. If there is an even number of bits with the value 1, the parity bit 155A-155C can be assigned the value 0. If there are an odd number of bits with the value 1, the parity bit 155A-155C can be assigned the value 1.

TABLE 2

| Sample Data | Number of Ones | Parity | Number of Ones |
|---|---|---|---|
| Bits in a Byte | in Data Byte | Bit | Including Parity Bit |
| 00000000 | 0 | 0 | 0 |
| 10110011 | 5 | 1 | 6 |
| 10010100 | 3 | 1 | 4 |
| 11111111 | 8 | 0 | 8 |

After the parity generator 142 has created the correct parity bit 155A-155C, the parity bit 155A-155C can be sent to the PPRAM 140 to be added and stored with the corresponding static data copy 154A-154C from which it was generated. Note that while Tables 1 and 2 above show example parity bits 155A-155C assigned for data bits in example data bytes, any data bytes and corresponding parity bits 155A-155C can be used.

Each time the microprocessor 132 reads one of the static data copies 154A-154C through the data bus 136, the static data copy 154A-154C being read can also be sent to the parity generator 142. The parity generator 142 can create a new parity bit 157 for the static data copy 154A-154C being read. The parity generator 142 can send this new parity bit 157 to the parity checker 144. At the same time, the PPRAM 140 can send the parity bit 155A-155C stored for the same static data copy 154A-154C being read to the parity checker 144. The control system 130 is therefore able to compare the original parity bit 155A-155C with the new parity bit 157.

The parity checker 144 can compare the two parity bits 155A-155C, 157 to determine if they match. If a bit changes from a zero to a one or from a one to a zero, the parity bit 157 that is output by the parity generator 142 can also change. If the parity checker 144 determines that the parity bits 155A-155C, 157 do not match, a bit in the static data copy 154A-154C has changed, and the static data copy 154A-154C has a parity fault indicating an error. The control system 130 could suffer an SEU by using a static data copy 154A-154C having a parity fault. When the comparison of parity bits 155A-155C, 157 indicates that a fault has occurred, the parity checker 144 can signal the microprocessor 132 that a fault has occurred.

In this example, only the PPRAM 140 may be subject to having static data copies 154A-154C suffer a bit value change that can cause an SEU. The ROM 134 does not need to be protected from a bit value change because the ROM 134 cannot be overwritten. Because the software run within the control system 130 may require more memory than can be offered by the ROM 134, the PPRAM 140 can be used to store the static data copies 154A-154C during software execution. By employing the parity bit checking, the control system 130 is able to detect any errors created in the static data copies 154A-154C that could cause an SEU.

In some embodiments, the data bus 136 and the address bus 138 may both represent 32-bit buses. However, a larger or smaller data bus 136 and/or a larger or smaller address bus 138 may be used depending on control system requirements.

The programs or other logic executed by the control system 130, such as by the microprocessor 132, can be used to implement BITE function PDIs as described in more detail below. For example, code used to implement BITE functions as PDIs could be stored in the ROM 134 and could (i) be copied to the PPRAM 140 for execution and/or (ii) process data stored in the PPRAM 140 during execution.

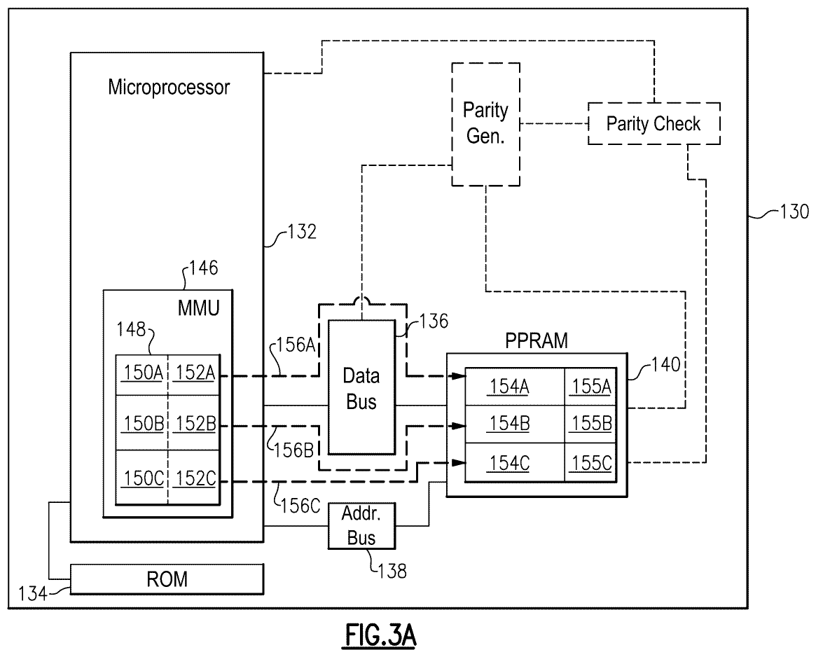

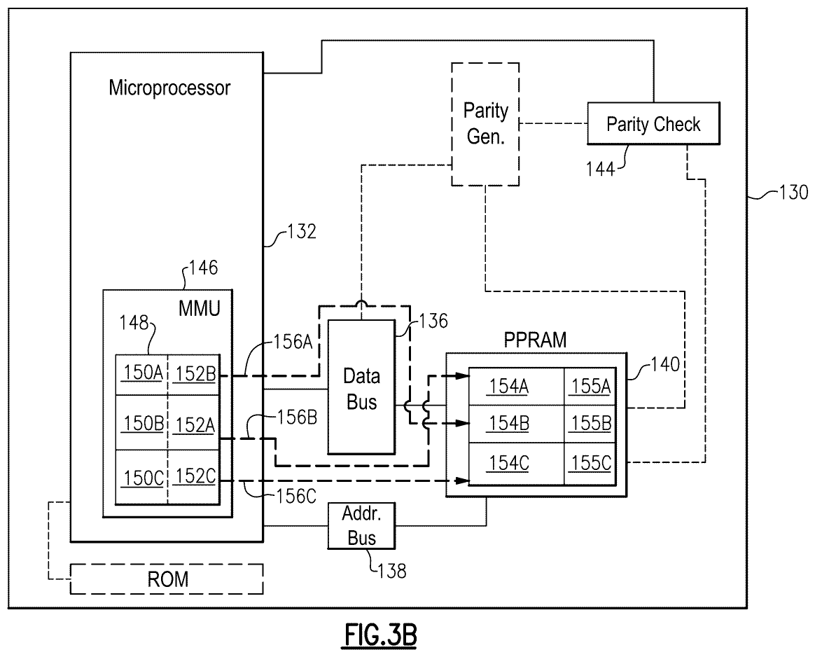

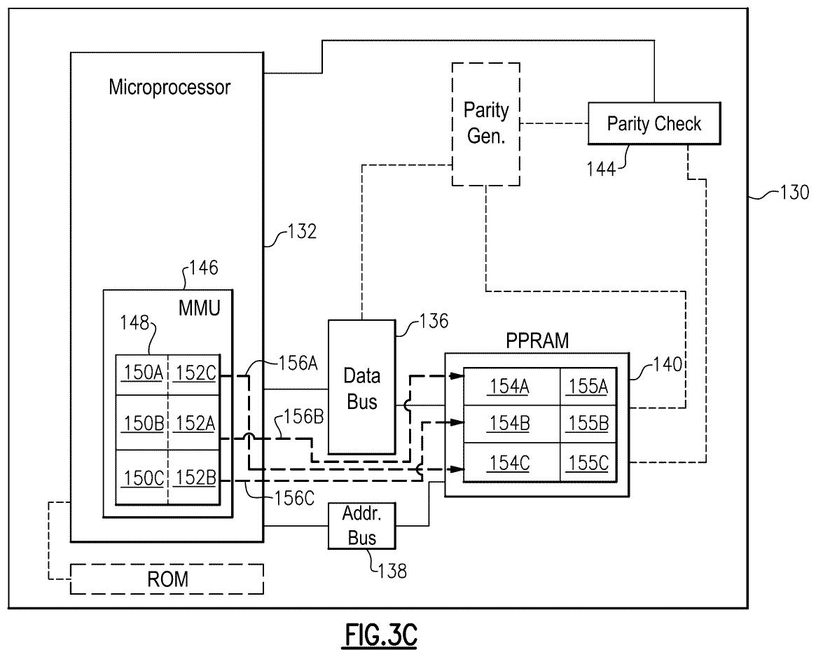

FIGS. 3A through 3C illustrate example portions of the control system 130 of FIG. 2 with data address mapping and reconfigured data address mapping in accordance with this disclosure. As shown in FIG. 3A and with continued reference to FIG. 2, when the microprocessor 132 sends the static data copies 154A-154C provided from the ROM 134 to the PPRAM 140, the memory address(es) for each static data copy 154A-154C can be provided to the MMU 146 by the address bus 138. The MMU 146 can include an MMU table 148 having logical pages 150A-150C and physical pages 152A-152C for each static data copy 154A-154C sent to the PPRAM 140. Each logical page 150A-150C can include a logical address that points to a physical page 152A-152C. Each physical page 152A-152C can include a physical address for each static data copy 154A-154C sent to the PPRAM 140. The logical address for each static data copy 154A-154C can be where the static data copy 154A-154C is assumed to reside when the control system 130 is reading the static data copy 154A-154C. The physical address can indicate the address where the static data copy 154A-154C is actually located in the PPRAM 140.

During operation of the control system 130, each static data copy 154A-154C can be mapped to a physical address stored in a corresponding physical page 152A-152C. The physical address stored in the physical page 152A can point to the corresponding static data copy 154A as indicated by arrow 156A. The physical address stored in the physical page 152B can point to the corresponding static data copy 154B. The physical address stored in the physical page 152C can point to the corresponding static data copy 154C. Similarly, the logical address stored in each logical page 150A-150C can point to a corresponding physical address stored in the physical page 152A-152C. Therefore, the logical address of the logical page 150A can initially point to the physical address of the physical page 152A, the logical address of the logical page 150B can initially point to the physical address of the physical page 152B, and the logical address of the logical page 150C can initially point to the physical address of the physical page 152C.

In this example, when the microprocessor 132 has the data bus 136 read data, the data bus 136 and the address bus 138 can refer to the logical address in the logical page 150A to retrieve the appropriate static data copy 154A-154C. However, the data bus 136 and the address bus 138 may also use the logical address stored in the logical page 150B or the logical page 150C. In some cases, during operation, the microprocessor 132, the data bus 136, and the address bus 138 can determine the static data copy 154A-154C to use by using the same logical page 150A. Although only three static data copies 154A-154C with associated logical pages 150A-150C and physical pages 152A-152C are shown here, any number of logical pages, physical pages, and corresponding static data copies are within the scope of this disclosure.

Referring to FIG. 3B, when the parity checker 144 has detected a parity fault in the static data copy 154A, the parity checker 144 can notify the microprocessor 132. In response, the microprocessor 132 can reconfigure the MMU table 148. For example, the logical page 150A, which is being used by the data bus 136 and the address bus 138 to determine which static data copy 154A-154C to access, can be reconfigured to point to the physical address stored in the physical page 152B. The control system 130 thus avoids reliance on the static data copy 154A, which has a parity fault as indicated by the parity checker 144. By reconfiguring the logical page 150A, the control system 130 can continue normal operation without interruption, such as without rebooting the control system 130.

As a result of the reconfiguration of the MMU table 148, the logical page 150B can now point to the physical address stored in the physical page 152A, and the logical page 150C can point to the physical address stored in the physical page 152C. However, the physical address stored in the physical pages 152A-152C may not change. Therefore, the MMU 146 is able to point to a different static data copy 154A-154C that does not have an error.

Referring to FIG. 3C, when the parity checker 144 has detected a parity fault in the static data copy 154B, the parity checker 144 can notify the microprocessor 132. In response, the microprocessor 132 can reconfigure the MMU table 148. For example, the logical page 150A, which is being used by the data bus 136 and the address bus 138 to determine which static data copy 154A-154C to access, can be reconfigured to point to the physical address stored in the physical page 152C. The control system 130 thus avoids reliance on the static data copy 154B, which has a parity fault as indicated by the parity checker 144. By reconfiguring the logical page 150A, the control system 130 can continue normal operation without interruption.

As a result of the reconfiguration of the MMU table 148, the logical page 150B can now point to the physical address stored in the physical page 152B, and the logical page 150C can point to the physical address stored in the physical page 152A. However, the physical address stored in the physical pages 152A-152C may not change. Therefore, the MMU 146 is able to point to a different static data copy 154A-154C that does not have an error.

In this example, if the final physical page 152C is reached and the parity checker 144 detects a parity fault in the static data copy 154C, wrap-around can occur. That is, when this parity fault is detected, the logical page 150A can wrap around to again point to the physical address stored in the physical page 152A as shown in FIG. 3A. Therefore, the software being run in the control system 130 may not be interrupted.

Although FIG. 2 illustrates one example of a control system 130 for an aircraft 100 supporting parametric data items for built-in testing of aircraft electrical power generation systems or other components and FIGS. 3A through 3C illustrate example portions of the control system 130 of FIG. 2 with data address mapping and reconfigured data address mapping, various changes may be made to FIGS. 2 through 3C. For example, various components in FIGS. 2 through 3C may be combined, further subdivided, replicated, omitted, or rearranged and additional components may be added according to particular needs. Also, BITE functions implemented as PDIs may be used in any other suitable control system, such as one that does not include multiple copies 154A-154C of bytes of static data or one that includes two copies or more than three copies of bytes of static data. Again, in general, this disclosure is not limited to use with any specific type of control system.

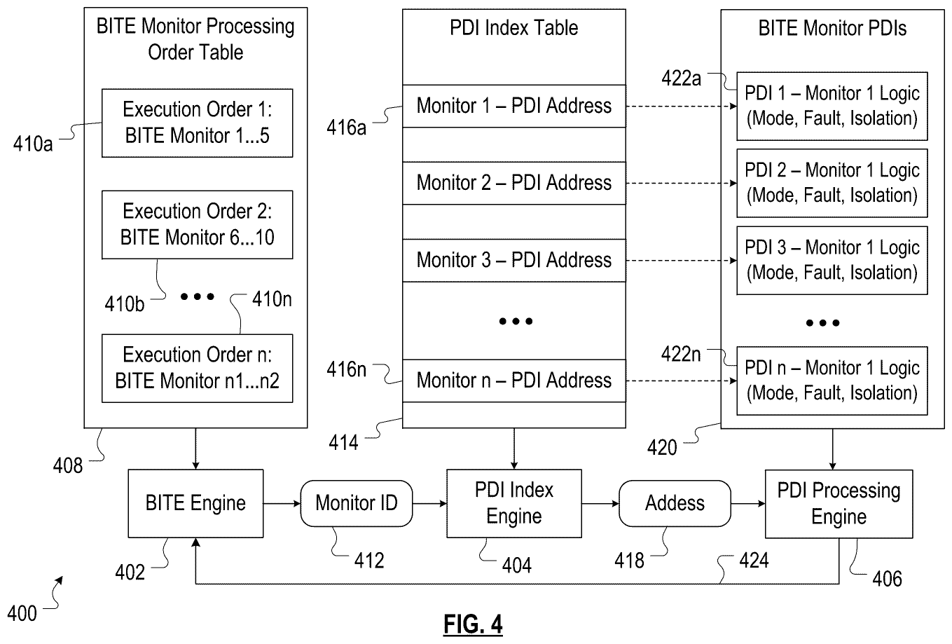

FIG. 4 illustrates an example architecture 400 supporting the development and management of PDIs for built-in testing of aircraft electrical power generation systems or other components in accordance with this disclosure. For ease of explanation, the architecture 400 shown in FIG. 4 is described as being used in the control system 130 shown in FIG. 2 within the aircraft 100 shown in FIG. 1. However, the architecture 400 shown in FIG. 4 could be used with any other suitable control system and/or with any other suitable type of aircraft.

As shown in FIG. 4, the architecture 400 includes a BITE engine 402, a PDI index engine 404, and a PDI processing engine 406. The BITE engine 402 generally operates to identify which BITE functions are to be executed for given BITE tests. The specific BITE functions to be executed could be defined in any suitable manner. For example, the specific BITE functions to be executed could be based on the specific control circuit(s) and/or power generation system(s) of a given type of aircraft 100. The specific BITE functions to be executed could also or alternatively be based on detected conditions of the aircraft 100, such as its current operational mode. The various BITE functions here are referred to as BITE monitors, and each BITE monitor can be associated with at least one BITE monitor PDI that implements that particular BITE monitor.

In this example, the BITE engine 402 has access to a BITE monitor processing order table 408. The BITE monitor processing order table 408 stores information that defines execution orders 410a-410n of BITE monitors for various BITE tests. For example, the execution order 410a can define a sequence of BITE monitors for one BITE test, the execution order 410b can define a sequence of BITE monitors for another BITE test, and the execution order 410n can define a sequence of BITE monitors for yet another BITE test. One or more of the BITE monitors here could be reusable across different BITE tests. For example, one or more of the BITE monitors could be reusable across BITE tests involving different aircraft 100 having different equipment configurations. Each execution order 410a-410n can identify any suitable sequence of BITE monitors used to implement a specified BITE test. The BITE monitor processing order table 408 can be created in any suitable manner. In some cases, the BITE monitor processing order table 408 can be created during compile time, such as during compiling of code used to implement the various BITE tests being supported. Note that the BITE monitor processing order table 408 can include any suitable number of execution orders.

In this example, the BITE engine 402 could retrieve an execution order 410a-410n for a given BITE test from the BITE monitor processing order table 408, such as by using a BITE monitor index to access the BITE monitor processing order table 408. Once an execution order 410a-410n is retrieved, the BITE engine 402 can provide a BITE monitor identifier (ID) 412 to the PDI index engine 404 for each BITE monitor in the retrieved execution order 410a-410n.

For each BITE monitor ID, the PDI index engine 404 generally operates to access a PDI index table 414 and identify a mapping 416a-416n that associates the BITE monitor ID with a PDI memory address. The PDI memory address identifies or can be used to identify where the corresponding BITE monitor PDI associated with the BITE monitor ID is stored in a memory. In this way, the PDI index table 414 can include or be used to identify the memory address pointing to each BITE monitor PDI associated with the retrieved execution order. Thus, when the selected execution order 410a-410n identifies a series of BITE monitors for a given BITE test, the PDI index engine 404 can output a series of PDI addresses 418 identifying locations of a series of BITE monitor PDIs to be executed to the PDI processing engine 406. The PDI index table 414 can be created in any suitable manner. In some cases, the PDI index table 414 can be created during compile time, such as during compiling of code used to implement the various BITE tests being supported. In some embodiments, the PDI index table 414 is a field-loadable software table or other table that can be loaded independently for each of the BITE tests. Note that the PDI index table 414 can include any suitable number of mappings/PDI memory addresses.

The PDI processing engine 406 generally operates to access at least one memory 420 (which could represent the ROM 134 and/or the PPRAM 140) containing BITE monitor PDIs 422a-422n using the identified addresses 418 and retrieve and execute the addressed BITE monitor PDIs 422a-422n. This allows the PDI processing engine 406 to execute the desired BITE test(s). Each BITE monitor PDI 422a-422n can include code or other logic that implements at least part of a particular BITE monitor. The BITE monitor (or portion thereof) implemented by any given BITE monitor PDI 422a-422n could vary depending on the circumstances. For example, various BITE monitor PDIs 422a-422n could be used to continuously monitor the health and/or performance of a power generation system (such as a generator, bus, transformer, and/or circuit breaker) onboard an aircraft 100. As particular examples, each BITE monitor PDI 422a-422n could define a mode in which monitoring occurs, a fault to be identified, and an isolation technique to be performed if a fault is identified. Note that the memory 420 can include any suitable number of BITE monitor PDIs.

In some cases, the PDI processing engine 406 can provide feedback 424, such as fault data, to the BITE engine 402. The feedback 424 could, for instance, identify or include fault data that is generated while the PDI processing engine 406 is executing one or more of the addressed BITE monitor PDIs 422a-422n. The BITE engine 402 could use the feedback 424 in any suitable manner. For example, the BITE engine 402 could use the feedback 424 to identify that a specified fault has been detected and select one or more additional execution orders 410a-410n associated with one or more additional BITE tests to be executed based on the specified fault.

During operation, the BITE engine 402 can read the execution order 410a-410n of BITE monitors from the BITE monitor processing order table 408 for a given BITE test. For each BITE monitor, the BITE engine 402 can send the associated BITE monitor ID 412 to the PDI index engine 404. The PDI index engine 404 can identify a PDI memory address associated with the BITE monitor ID 412 using the corresponding mapping 416a-416n in the PDI index table 414. The identified PDI memory address 418 can be sent to the PDI processing engine 406. The PDI processing engine 406 can retrieve each BITE monitor PDI 422a-422n to be executed based on the received PDI memory address 418, and the PDI processing engine 406 can execute the retrieved BITE monitor PDI 422a-422n. If needed or desired, the PDI processing engine 406 may interpret a current process that might be executing. Also, the PDI processing engine 406 may send any fault data generated while executing the BITE monitor PDIs 422a-422n to the BITE engine 402 as feedback 424.

As can be seen in FIG. 4, the BITE monitor IDs 412 effectively represent a parametric control parameter that can enable the selection of BITE monitor PDIs 422a-422n, where those BITE monitor PDIs 422a-422n can be retrieved and executed to provide desired BITE testing functionality. Based on the BITE monitor ID selection, the PDI index table 414 can point to the corresponding BITE monitor PDI 422a-422n. BITE monitor PDIs 422a-422n can be combined and used in any suitable manner, including reuse of at least some of the BITE monitor PDIs 422a-422n across different aircraft equipment configurations. In some embodiments, the PDI index table 414 or the BITE monitor PDIs 422a-422n in the memory 420 can include additional information like protection enabler flags and values for any configurable parameters, which can be connected to a protection function during compile time.

Although FIG. 4 illustrates one example of an architecture 400 supporting the development and management of PDIs for built-in testing of aircraft electrical power generation systems or other components, various changes may be made to FIG. 4. For example, various components in FIG. 4 may be combined, further subdivided, replicated, omitted, or rearranged and additional components may be added according to particular needs. Also, the architecture 400 may support any suitable number of BITE monitors using any suitable number of execution orders 410a-410n, mappings 416a-416n, and BITE monitor PDIs 422a-422n.

Note that the functionality shown in FIG. 4 may be implemented in any suitable manner. In some embodiments, the functionality shown in FIG. 4 may be implemented within an aircraft 100 using one or more control systems 130 of the aircraft 100. In other embodiments, the functionality shown in FIG. 4 may be implemented within an aircraft 100 using one or more devices or systems separate from (but potentially usable with) one or more control systems 130 of the aircraft 100.

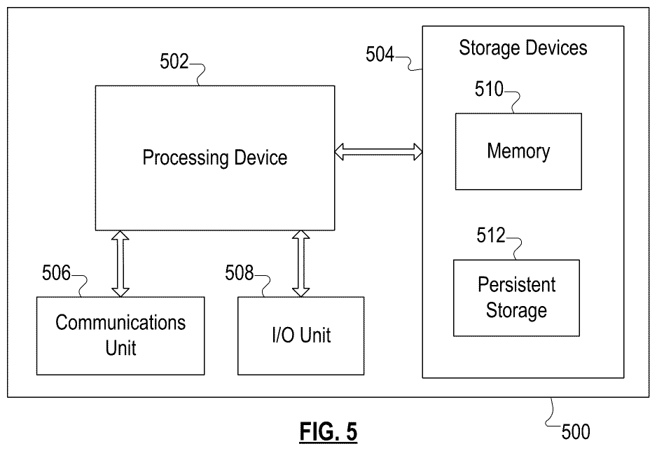

FIG. 5 illustrates an example device 500 for the development and management of parametric data items for built-in testing of aircraft electrical power generation systems or other components in accordance with this disclosure. For ease of explanation, the device 500 shown in FIG. 5 is described as being used in the aircraft 100 shown in FIG. 1, such as to monitor one or more generators 120, one or more control systems 130, and/or other components of the aircraft 100. However, the device 500 shown in FIG. 5 could be used with any other suitable type of aircraft and/or to monitor any other suitable type of aircraft equipment. In various embodiments, for instance, the device 500 may be used to at least partially implement one or more control systems 130 of the aircraft 100 or may be separate from and communicate with one or more control systems 130 of the aircraft 100.

As shown in FIG. 5, the device 500 denotes a computing device or system that includes at least one processing device 502, at least one storage device 504, at least one communications unit 506, and at least one input/output (I/O) unit 508. The processing device 502 may execute instructions that can be loaded into a memory 510. The processing device 502 includes any suitable number(s) and type(s) of processors or other processing devices in any suitable arrangement. Example types of processing devices 502 include one or more microprocessors, microcontrollers, digital signal processors (DSPs), application specific integrated circuits (ASICs), field programmable gate arrays (FPGAs), graphics processing units (GPUs), neural processing units (NPUs), or discrete circuitry. In some cases, the processing device 502 may represent or include the microprocessor 132.

The memory 510 and a persistent storage 512 are examples of storage devices 504, which represent any structure(s) capable of storing and facilitating retrieval of information (such as data, program code, and/or other suitable information on a temporary or permanent basis). The memory 510 may represent a random access memory or any other suitable volatile or non-volatile storage device(s). The persistent storage 512 may contain one or more components or devices supporting longer-term storage of data, such as a read only memory, hard drive, Flash memory, or optical disc. In some cases, the storage devices 504 may represent or include the ROM 134 and/or the PPRAM 140).

The communications unit 506 supports communications with other systems or devices. For example, the communications unit 506 can include a network interface card or a wireless transceiver facilitating communications over at least one wired or wireless connection. The communications unit 506 may support communications through any suitable physical or wireless communication link(s). In some cases, the communications unit 506 may represent or include one or more interfaces that support communications with other systems or devices of the aircraft 100, such as an electrical power generation system (like one or more generators 120) and a control circuit (like one or more GCUs) of the aircraft 100.

The I/O unit 508 allows for input and output of data. For example, the I/O unit 508 may provide a connection for user input through a keyboard, mouse, keypad, touchscreen, or other suitable input device. The I/O unit 508 may also send output to a display, printer, or other suitable output device. Note, however, that the I/O unit 508 may be omitted if the device 500 does not require local I/O, such as when the device 500 represents a device that can be accessed remotely.

In some embodiments, the instructions executed by the processing device 502 include instructions that implement the functionality of the architecture 400. Thus, for example, the instructions executed by the processing device 502 may include instructions implementing the BITE engine 402, PDI index engine 404, and PDI processing engine 406.

Although FIG. 5 illustrates one example of a device 500 for the development and management of parametric data items for built-in testing of aircraft electrical power generation systems or other components, various changes may be made to FIG. 5. For example, computing and communication devices and systems come in a wide variety of configurations, and FIG. 5 does not limit this disclosure to any particular computing or communication device or system.

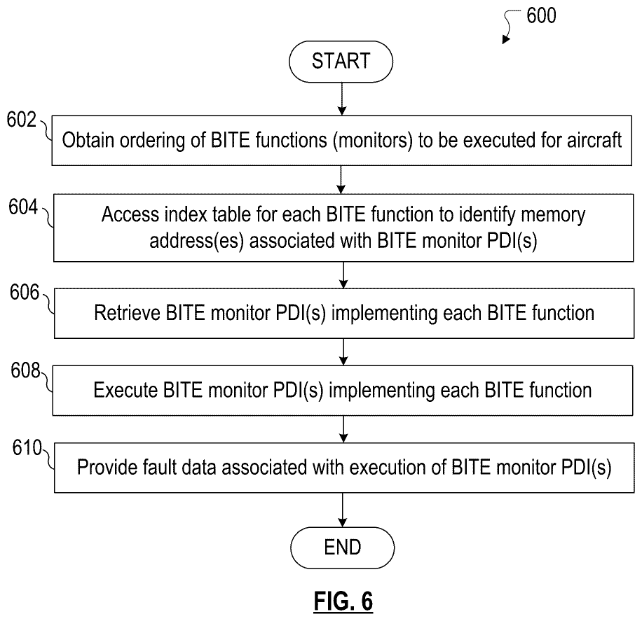

FIG. 6 illustrates an example method 600 for the development and management of parametric data items for built-in testing of aircraft electrical power generation systems or other components in accordance with this disclosure. For ease of explanation, the method 600 shown in FIG. 6 is described as being performed using the architecture 400 shown in FIG. 4, which could be used in the control system 130 shown in FIG. 2 or the device 500 of FIG. 5 within the aircraft 100 shown in FIG. 1. However, the method 600 shown in FIG. 6 could be performed using any other suitable architecture, in any other suitable control system or device, and/or within any other suitable type of aircraft.

As shown in FIG. 6, an ordering of BITE functions (BITE monitors) to be executed for an aircraft is obtained at step 602. This may include, for example, the microprocessor 132 executing the BITE engine 402 to access the BITE monitor processing order table 408 and identify an execution order 410a-410n for a specified BITE test. The identified execution order 410a-410n can identify a number of BITE monitors to be executed in order to implement the specified BITE test. Note that the specified BITE test could be associated with any desired number of BITE monitors.

For each identified BITE function, an index table can be accessed in order to identify one or more memory addresses associated with one or more BITE monitor PDIs for that BITE function at step 604. This may include, for example, the microprocessor 132 executing the PDI index engine 404 in order to receive a BITE monitor ID 412 for each BITE monitor identified in the execution order 410a-410n retrieved from the BITE monitor processing order table 408. This may also include the microprocessor 132 executing the PDI index engine 404 in order to access the PDI index table 414 and use a corresponding mapping 416a-416n to identify a PDI memory address 418 for each BITE monitor ID 412.

The BITE monitor PDI(s) implementing each BITE function are retrieved at step 606 and executed at step 608. This may include, for example, the microprocessor 132 executing the PDI processing engine 406 to use the PDI memory address(es) 418 for each BITE monitor to access the at least one memory 420 and retrieve one or more BITE monitor PDIs 422a-422n. This may also include the microprocessor 132 executing the PDI processing engine 406 in order to execute each of the retrieved BITE monitor PDIs 422a-422n and perform a desired BITE test. At least one of the executed BITE monitor PDIs 422a-422n can be used to implement one or more BITE functions that are configured to monitor an electrical power generation system of the aircraft 100 and/or a control circuit for the electrical power generation system of the aircraft 100.

Optionally, fault data associated with execution of at least one of the BITE monitor PDIs may be provided at step 610. This may include, for example, the microprocessor 132 executing the PDI processing engine 406 to provide feedback 424 indicative of or containing fault data to the BITE engine 402. The fault data may be used in any suitable manner, such as when used by the BITE engine 402 to select one or more additional BITE tests to be performed.

As noted above, at least some of the BITE monitor PDIs 422a-422n here can be reusable across different aircraft 100 having different equipment configurations. This can help to simplify the development of BITE tests for various aircraft configurations. Moreover, the BITE monitor PDIs 422a-422n that implement various BITE functions can be independent of one another. As a result, a modification can be made to one BITE monitor PDI 422a-422n and may not require alteration of other BITE monitor PDIs 422a-422n, even those BITE monitor PDIs 422a-422n used in the same execution order 410a-410n for the same BITE test. Again, this can help to simplify the development of BITE tests and facilitate updating or replacement of individual BITE monitor PDIs 422a-422n without requiring redesign of entire BITE tests.

Although FIG. 6 illustrates one example of a method 600 for the development and management of parametric data items for built-in testing of aircraft electrical power generation systems or other components, various changes may be made to FIG. 6. For example, while shown as a series of steps, various steps in FIG. 6 may overlap, occur in parallel, occur in a different order, or occur any number of times (including zero times). As a particular example, the method 600 may be repeated any number of times to perform any suitable number of BITE tests.

It should be noted that the functions described above can be implemented in a server or other electronic device(s) in any suitable manner. For example, in some embodiments, at least some of the functions described above can be implemented or supported using one or more software applications or other software instructions that are executed by the processing device(s) of one or more electronic devices, such as one or more electronic devices within an aircraft. In other embodiments, at least some of the functions described above can be implemented or supported using dedicated hardware components. In general, the functions described above can be performed using any suitable hardware or any suitable combination of hardware and software/firmware instructions. Also, the functions described above can be performed by a single electronic device or by multiple electronic devices.

In some embodiments, various functions described in this patent document are implemented or supported by a computer program or other program that is formed from computer readable program code or instructions and that is embodied in a computer or machine readable medium. The phrases “computer readable program code” and “instructions” include any type of code, including source code, object code, and executable code. The phrases “computer readable medium” and “machine readable medium” include any type of medium capable of being accessed by a computer or other machine, such as read only memory (ROM), random access memory (RAM), a hard disk drive (HDD), a compact disc (CD), a digital video disc (DVD), or any other type of memory. A “non-transitory” computer or machine readable medium excludes wired, wireless, optical, or other communication links that transport transitory electrical or other signals. A non-transitory computer or machine readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
obtaining an ordering of built-in test equipment (BITE) functions to be executed for an aircraft; and
for each BITE function of the ordering, retrieving and executing at least one parametric data item (PDI) implementing the BITE function;
wherein at least some of the PDIs implementing the BITE functions are independent of one another such that a modification to one PDI does not alter others of the other PDIs; and
wherein at least some of the PDIs are reusable across different aircraft having different equipment configurations.

2. The method of claim 1, wherein obtaining the ordering of the BITE functions comprises obtaining the ordering of the BITE functions from an ordering table using a BITE engine.

3. The method of claim 2, wherein retrieving and executing the at least one PDI implementing the BITE function comprises, for each BITE function of the ordering:
accessing an index table using a PDI index engine, the index table accessed based on an identifier provided by the BITE engine; and
retrieving the at least one PDI implementing the BITE function from memory using a PDI processing engine, the at least one PDI retrieved using at least one memory address provided by the PDI index engine from the index table.

4. The method of claim 2, wherein the ordering table identifies multiple orderings of BITE functions.

5. The method of claim 2, further comprising:
providing fault data associated with execution of at least one of the PDIs to the BITE engine.

6. The method of claim 1, wherein at least one of the BITE functions is configured to monitor an electrical power generation system of the aircraft, a control circuit for the electrical power generation system of the aircraft, or both.

7. The method of claim 1, wherein the different equipment configurations comprise at least one of:
different electrical power generation systems; or
different control circuits for electrical power generation systems.

8. An apparatus comprising:
at least one memory configured to store parametric data items (PDIs) implementing built-in test equipment (BITE) functions; and
at least one processing device configured to:
obtain an ordering of the BITE functions to be executed for an aircraft; and
for each BITE function of the ordering, retrieve and execute at least one PDI implementing the BITE function;
wherein at least some of the PDIs implementing the BITE functions are independent of one another such that a modification to one PDI does not alter others of the other PDIs; and
wherein at least some of the PDIs are reusable across different aircraft having different equipment configurations.

9. The apparatus of claim 8, wherein the at least one processing device is configured to obtain the ordering of the BITE functions from an ordering table using a BITE engine.

10. The apparatus of claim 9, wherein, to retrieve and execute the at least one PDI implementing the BITE function, the at least one processing device is configured, for each BITE function of the ordering, to:
access an index table using a PDI index engine, the index table accessed based on an identifier provided by the BITE engine; and
retrieve the at least one PDI implementing the BITE function from the at least one memory using a PDI processing engine, the at least one PDI retrieved using at least one memory address provided by the PDI index engine from the index table.

11. The apparatus of claim 9, wherein the ordering table identifies multiple orderings of BITE functions.

12. The apparatus of claim 9, wherein the at least one processing device is further configured to provide fault data associated with execution of at least one of the PDIs to the BITE engine.

13. The apparatus of claim 8, wherein at least one of the BITE functions is configured to monitor an electrical power generation system of the aircraft, a control circuit for the electrical power generation system of the aircraft, or both.

14. The apparatus of claim 8, wherein the different equipment configurations comprise at least one of:
different electrical power generation systems; or
different control circuits for electrical power generation systems.

15. A non-transitory machine-readable medium containing instructions that when executed cause at least one processor to:
obtain an ordering of built-in test equipment (BITE) functions to be executed for an aircraft; and
for each BITE function of the ordering, retrieve and execute at least one parametric data item (PDI) implementing the BITE function;
wherein at least some of the PDIs implementing the BITE functions are independent of one another such that a modification to one PDI does not alter others of the other PDIs; and
wherein at least some of the PDIs are reusable across different aircraft having different equipment configurations.

16. The non-transitory machine-readable medium of claim 15, wherein the instructions when executed cause the at least one processor to obtain the ordering of the BITE functions from an ordering table using a BITE engine.

17. The non-transitory machine-readable medium of claim 16, wherein the instructions that when executed cause the at least one processor to retrieve and execute the at least one PDI implementing the BITE function comprise:
instructions that when executed cause the at least one processor, for each BITE function of the ordering, to:
access an index table using a PDI index engine, the index table accessed based on an identifier provided by the BITE engine; and
retrieve the at least one PDI implementing the BITE function from memory using a PDI processing engine, the at least one PDI retrieved using at least one memory address provided by the PDI index engine from the index table.

18. The non-transitory machine-readable medium of claim 16, wherein the ordering table identifies multiple orderings of BITE functions.

19. The non-transitory machine-readable medium of claim 16, further containing instructions that when executed cause the at least one processor to provide fault data associated with execution of at least one of the PDIs to the BITE engine.

20. The non-transitory machine-readable medium of claim 15, wherein at least one of the BITE functions is configured to monitor an electrical power generation system of the aircraft, a control circuit for the electrical power generation system of the aircraft, or both.
